(19) United States
(12) Patent Application Publication
(10) Pub. No.: US 2002/0175716 A1
(43) Pub. Date: Nov. 28, 2002

(54) Ultra high speed clocked limiting preamplifier

(75) Inventor: Sasan Cyrusian, Scotts Valley, CA (US)

Correspondence Address: BRINKS HOFER GILSON & LIONE, P.O. BOX 10395, CHICAGO, IL, 60611, US

(73) Assignee: Infineon Technologies North America Corp.

(21) Appl. No.: 09/865,791

(22) Filed: May 25, 2001

(51) Int. Cl. H03B 1/00

(52) U.S. Cl. 327/108

(57) ABSTRACT

An ultra high-speed clocked limiting preamplifier is revealed, useful especially at speeds exceeding 1 GHz. The preamplifier is useful in comparing an analog input signal to a reference voltage, and then pre-amplifying the signal for further processing. The preamplifier is designed for accepting a time-varying input voltage, processing the signal through one or more stages of preamplification, and then converting the signal to a digital output. The preamplifier is useful in analog to digital converters (ADCs) and clock data recovery circuits.

### RELATED APPLICATION

The present application is related to U.S. patent application ______, now U.S. Pat. No. ______ , entitled Ultra High Speed Clocked Analog Latch, filed on the same day as the present application by the inventor of the present invention and assigned to the assignee of the present invention. The entire contents of the application are hereby incorporated by reference.

### BACKGROUND OF THE INVENTION

The present invention relates generally to preamplifiers, and more particularly the present invention relates to high-speed preamplifiers for analog to digital converters that are able to achieve a very high gain in a very short time. Such preamplifiers are useful, for example, in read/write channels for computer hard drives. In many applications, it is desirable to achieve a very high gain in a very short time, such as in computers or computer peripherals running at very high clock rates. In some cases, it is not necessary that a particular amplification be exact, but that it be fast, or in other words, so long as the amplification reaches a certain level, that is sufficient. Complicating the situation are certain drawbacks for amplifiers or pre-amplifiers having high gain. In general, an amplifier having high gain tends to leave a residual voltage offset on the preamplifier between cycles. Complementary metal oxide semiconductor (CMOS) preamplifiers also suffer from offset voltage, caused primarily by fabrication mismatch between the input stage transistors. A reset operation may be needed during every clock cycle. Thus, it may be necessary to run an auto-zero operation more than one time in order to remove such offsets, so that an analog to digital converter using the preamplifier is not left with a false residual signal.

FIG. 1 depicts a prior art preamplifier 100. The preamplifier 100 has a simple construction, with an input section 110, an output section 120, a voltage supply 102 and a current source 118. The input section 110 has input voltage terminals 108 and two input transistors 112 for receiving and amplifying an input voltage signal to the gates of the input transistors. The input voltage signal is a time-varying signal. The output section has two pull-up resistors 120, a reset transistor 116, and output terminals 122. In the input section, two transistors 114 are arranged in cascode with the input transistors to further increase the output impedance of the amplifier and thus the amplification. The drains of the cascode transistors are connected to output terminals 122. Pull-up resistors 120 load the output of the amplifier 100 and make possible a high DC gain. Current flows in the direction of the small arrow, and current source 118 delivers a steady current to the circuit, controlled by the first bias voltage 124 applied to the gate of current source 118. A voltage is applied to the gate of reset amplifier 116 in the first half of every clock cycle. This shorts the drain of the transistor to the source, removing residual voltage from the previous clock cycle, and setting both terminals to the same voltage. The second bias voltage applied to the gates of the cascode transistors 114 also sets the steady-state gain of the amplifier. The amplifier thus amplifies a very small voltage input signal by a factor of about five. A circuit with higher gain is needed. In addition, using resistors in this manner will increase the output resistance of the circuit, but also uses up a good part of the available positive voltage as an IR drop across the resistors, and thus unavailable at the differential output terminals. Therefore, a circuit with higher output resistance but also higher voltage is desired.

FIG. 2 depicts an improved prior art preamplifier that overcomes some of the disadvantages of the circuit of FIG. 1. FIG. 2 shows a high gain DC preamplifier 200 that has a voltage supply 202, a current source 218, an input section 210 and an output section 230. The input section includes input terminals 208, input transistors 212, and transistors 214 cascoded with the input transistors 212. The amplifier has a voltage supply 202 and a current source 218 to power the amplifier. Current source 218 receives bias voltage 224 at its gate and operates at a constant current. The input voltage signal is a time-varying signal applied to the input terminals 208. The output section includes reset transistor 216, output terminals 228, and four transistors 220, 222. Two transistors 220 are connected as a positive feedback load, with the gate of one connected to the drain of the other. Additional transistors 222 are also connected as MOS diode loads in parallel with the positive feedback transistors 220, the gates of the MOS transistors 222 connected to their drains. The effect of the positive feedback loads and the MOS diode loads is twofold. The positive feedback transistors 220 increase the output resistance and thus the DC gain of the preamplifier 200. This technique, with transistors, uses less voltage drop than with the pull-up resistors in the circuit of FIG. 1. The diode-connected MOS transistors 222 lessen this resistance, and thus limit the DC gain of the amplifier 200, but with a much higher gain, about 10.

Unfortunately, the improvements of circuits such as these are limited. For instance, to achieve more resistance and more gain, the length of the MOS channel in these transistors must be increased. But since the gate of the transistors is connected to the output terminals 228, any increase in gate length will result in an increase in output capacitance and thus an increase in the time constant of the amplifier 200, slowing it down. What is needed is a design to increase the DC gain and the DC resistance of such a preamplifier, without affecting its speed or responsiveness, or its ability for stable feedback from outputs to the inputs of the amplifier for removing offset voltage.

### BRIEF SUMMARY

The present embodiments meet this need by providing a high-speed preamplifier with very high DC gain and an auto-zero capability. In one embodiment, a preamplifier comprises an input section and an output section. The input section includes a first input transistor and a second input transistor, gates of the transistors connected to input terminals of the preamplifier, for applying an input differential voltage signal. The input transistors are also connected in cascode with a third and a fourth transistor to increase the output impedance of the amplifier. A tail current source transistor is connected between the joined sources of the first and second input transistors and a return of a voltage supply for the preamplifier. The circuit is designed for a time-varying input signal and high-speed clocked operation. The output section is connected to the input section at output terminals. A first and a second current source transistor are connected between a voltage supply and the output terminals, acting as loads for the amplifier and maintaining its ability to generate high gain. A reset transistor may also be connected across the output terminals. The preamplifier of this construction produces an output having high gain and high output resistance. Many other embodiments of the preamplifier are also possible.

### BRIEF DESCRIPTION OF SEVERAL VIEWS OF THE DRAWINGS

FIGS. 1 and 2 illustrate prior art amplifiers.

FIG. 3 is an embodiment of a high-speed amplifier having DC gain.

FIG. 4 is another embodiment of a high-speed amplifier with high gain and a common mode current feedback loop.

FIG. 5 is another embodiment incorporating an autozero section.

FIG. 6 is another embodiment incorporating a comparator section.

FIG. 7 depicts another embodiment employing a feedback loop.

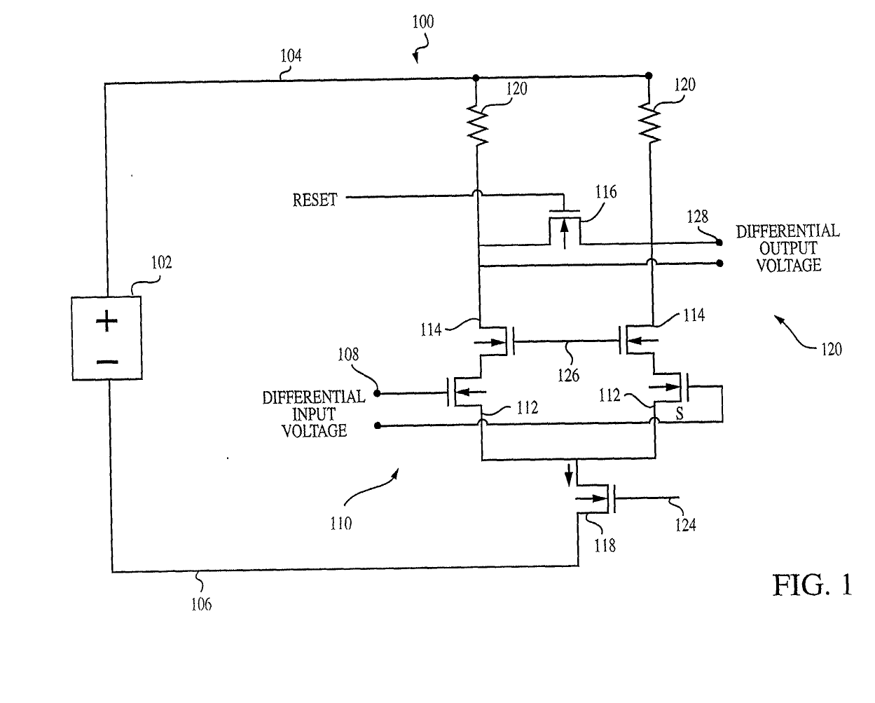

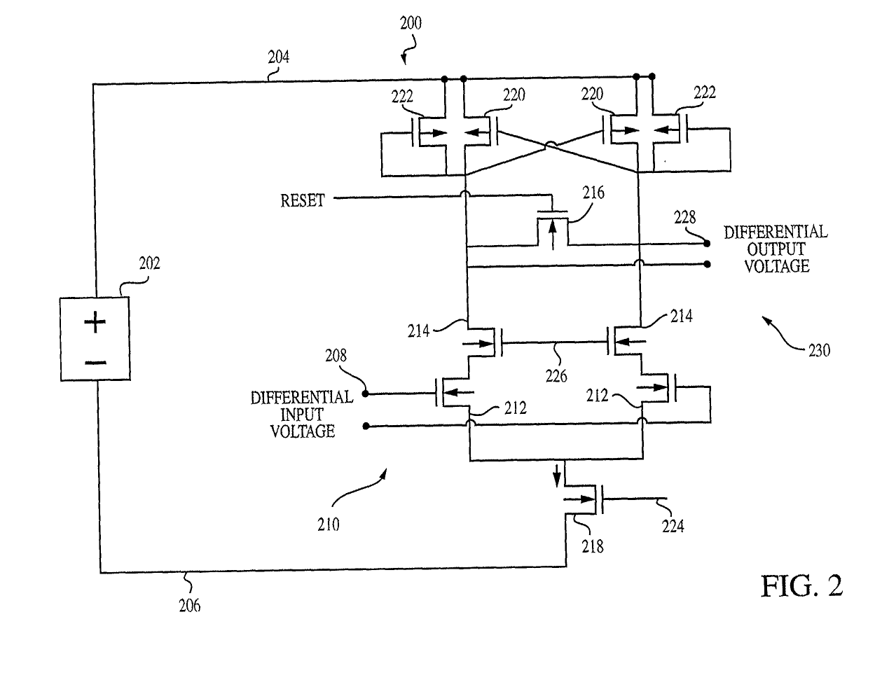

### DETAILED DESCRIPTION OF THE PRESENTLY PREFERRED EMBODIMENTS

In the discussion below, transistors are described as CMOS transistors, and in particular as p-channel MOS (PMOS) or n-channel MOS (NMOS) transistors. Those skilled in the art will recognize that the terms p-channel and n-channel might more accurately describe the transistors discussed herein, since these transistors are typically not manufactured by depositing metallic elements, except possibly for external connections. Rather, source and drain regions are doped to either p-type or n-type, indicating whether the channel between source and drain conducts via depletion mode (holes) or enhancement mode (electrons). Nevertheless, the terms PMOS and NMOS are more-commonly used, and are so used herein to mean those transistors manufactured by CMOS processes.

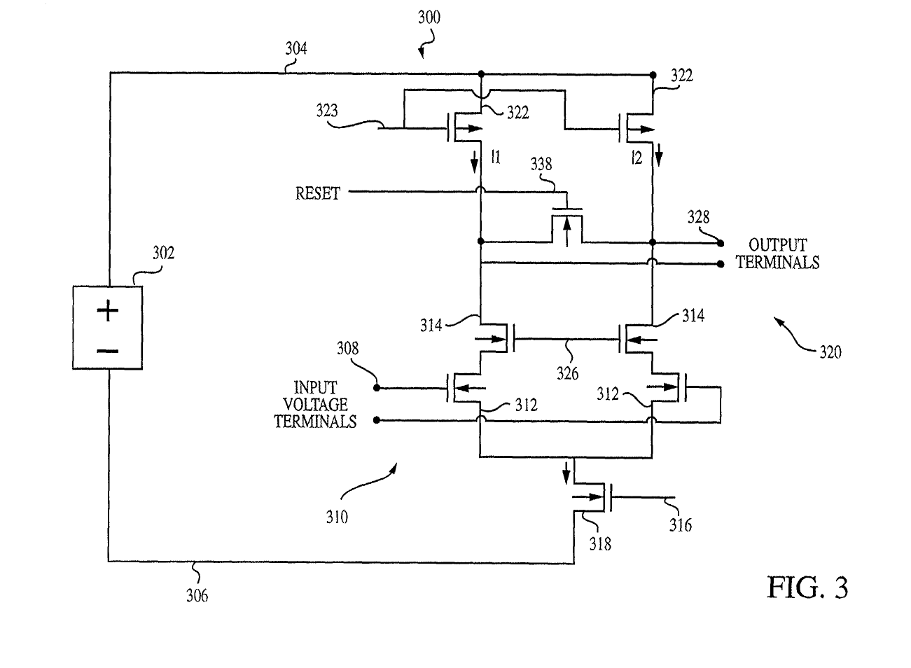

An improved preamplifier 300 with high speed and high DC gain is depicted in FIG. 3. The amplifier 300 is connected to a voltage supply 302 having a positive supply 304 and a negative supply or return 306. The preamplifier 300 has input terminals 308 for applying a differential time-varying signal and amplifying it by a factor significantly larger than 10. The preamplifier has an input section 310 and an output section 330, the input and output sections joined at output terminals 328. The output terminals need not be discrete components, but may be any point of contact between traces or conductive paths of the preamplifier. Thus, the words “inputs” or “outputs” or “terminals,” whether applied to input terminals, output terminals, or a point of input voltage or current to any drain, source or gate, may mean any points of contact, rather than specific components meant for assembly.

The input section includes first and second input transistors 312, connected at their gates to the input voltage terminals. Also included are a third transistor 314 and a fourth transistor 314 connected in cascode between the first and second transistors 312, and controlled by a bias voltage 326 applied to the gates of transistors 314. By cascode is meant that the drain of one transistor is connected to the source of the next in this circuit. The drains of the cascode transistors 314 are connected to the output terminals 328. The output section includes transistors 322 connected between the positive supply voltage 304 and the output terminals 328. Completing the circuit to the power supply return 318 is a tail current source transistor 318, connected between the sources of the input transistors 312 and a return 306 of the power supply. Bias voltage 316 at the gate of transistor 318 controls the current flow. Transistors 322 function as current sources for the preamplifier 300, passing a constant current set by a first bias voltage 316 applied to a tail current source transistor 318 and by second bias voltage 323 applied to gates of the current source transistors 322.

The preamplifier 300 is meant to amplify an input voltage signal that is typically measured as a microvolt, the preamplifier 300 requiring a high output resistance and intended to produce an amplified voltage but not a high current. Therefore, tail current source 318 and current sources 322 are designed to pass small currents as indicated by the small arrows, the current intended to function as a load for the amplifier, rather than as current meant to flow in the output terminals. Tail current source 318 should not limit the current flow of transistors 322, and desirably has a channel W and L (width and length of the n-channel) sufficient to accommodate the current flow from current sources 322.

Note that only the drains of current source transistors 322 are connected to the output terminals 328. Therefore, one method of increasing the output resistance of these transistors, and therefore that of the preamplifier, is to lengthen the p-channel of these PMOS transistors. Alternatively, the width of the channel may be narrowed. The intrinsic resistance of the transistor may thus be increased. However, since only the drain is connected to the output terminals, the output load capacitance of the output section of the preamplifier, and thus the time constant of the preamplifier, is barely affected. Thus, the preamplifier may have higher gain, a controlled load, and very little effect on its speed or responsiveness to a time-varying DC input signal. Another transistor, reset transistor 338, may be added across the output terminals 328 of the preamplifier. The reset transistor shorts the output terminals to each other when a reset signal is applied to the gate of the reset transistor. This function may also be useful in operating the preamplifier. In one embodiment, the gain of the preamplifier is a factor of about 3 to 5 over the input voltage differential for the available time for amplification, depending on the input signal frequency, about 1 microsecond or less. In another embodiment, the gain factor is about 5 to 10 for the available time for amplification. Other embodiments are possible.

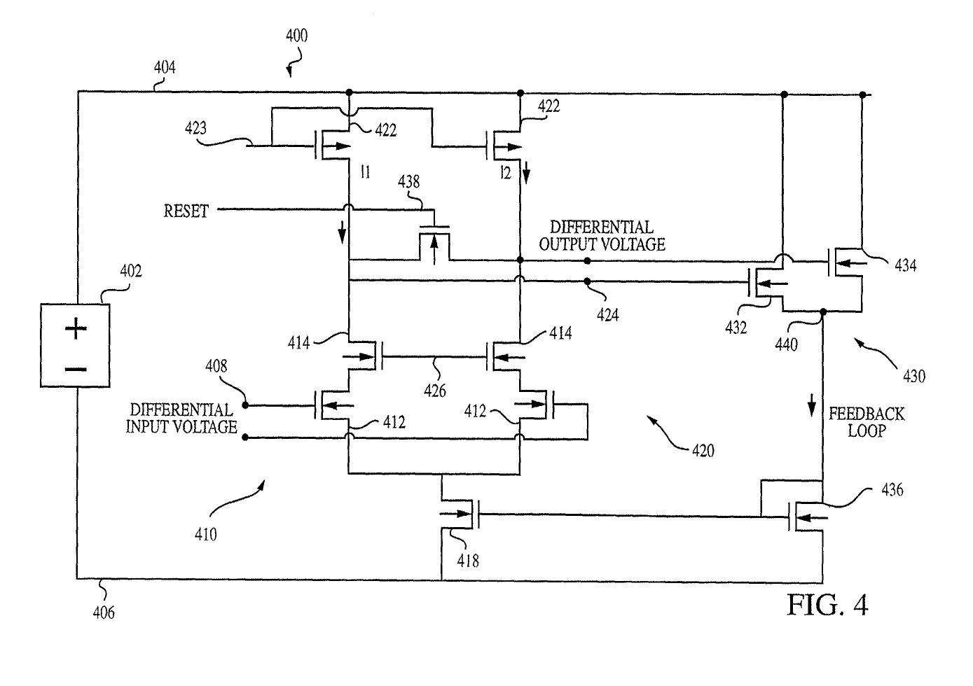

A further improvement to the preamplifier is depicted in FIG. 4. As discussed for FIG. 3, the input section 410 of preamplifier 400 includes a power supply 402 having a positive rail 404 and a negative or return rail 406. The input section 410 includes input terminals 408 connected with first and second input transistors 412, and also with first and second cascode transistors 414. The input section 410 connects with output terminals 424 at the drains of the cascode transistors 414. The output section 420 includes current source transistors 422 connected to the positive voltage supply 404, the drains of the current source transistors 422 also being connected to the output terminals 424.

A tail current source transistor 418 completes the circuit by connecting the sources of the input transistors 412 to the voltage supply return 406. A reset transistor 438 may also be connected across the output terminals 424 to short the terminals when desired. Bias voltages 426 and 423 control the operation of transistors 414 and 422, respectively. The preamplifier 400 adds a common mode feedback current loop 430 in order that the sum of currents 11 and 12 in the output section 420 may stay balanced with the tail current of transistors 418 and 436.

The feedback loop 430 includes first and second feedback loop transistors 432, 434, connected in parallel with the positive voltage supply 404 and a second tail current source transistor 436. The combined sources of the first and second feedback loop transistors 432, 434 are connected to the drain and gate of the second tail current source transistor 436. First and second tail source transistors 418, 436 are connected as a current mirror, having a common source at the voltage supply return 406 and having joined gates 416. The sources of transistors 432, 434 are joined at an averaging node 440. The direction of current in the feedback loop is as shown by the small arrow.

Because of the high output impedance of the preamplifier 400, minor differences between the tail current in tail current transistor 418, and the sum of I1 and I2 in the current source transistors 422, may affect the common mode voltage. This circuit utilizes the transconductance of feedback transistors 432, 434 operating as non-linear averaging resistors with the second tail current source 436 connected to the averaging node 440. The voltage available at the gate of feedback transistor 432, and thus one output terminal, is the sum of gate-to-source voltage (Vgs) for transistor 432 and Vgs for transistor 436. The voltage available at the other terminal is the sum of Vgs for transistor 434 and Vgs for transistor 436.

The feedback loop works by providing feedback so that the currents provided by current sources 422 are equal to the tail current provided by tail current transistors 418 and 436. The current feedback loops works thusly. If the current in the current source transistors 422 rises, then their drain voltages and the voltages applied to the gates of feedback transistors 432, 434 rises. Vgs for transistors 432, 434 also rises, increases the drain voltage at tail current transistor 436 and also increasing the gate voltage for tail current transistors 418 and 436. With increased gate voltages, the current of tail current transistors 418 and 436 also rises. Thus, an increase in current from the current source transistors 422 is matched by increases in tail current from tail current transistors 418 and 436. The feedback loop works in a corresponding manner for decreases in current. The first tail current transistor 418 carries the bulk of the current.

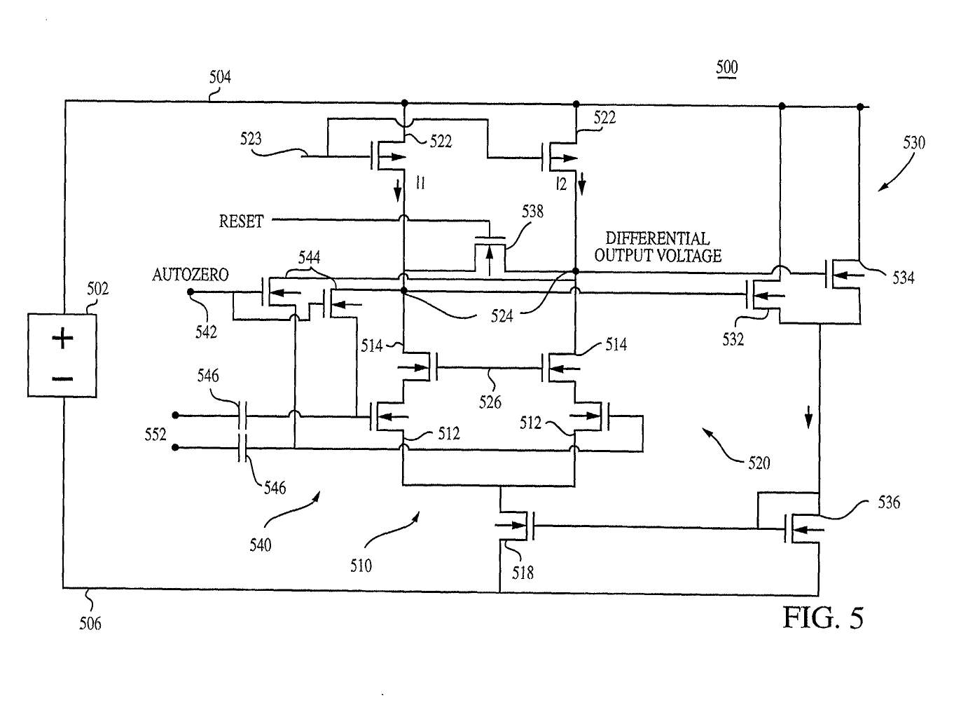

A further improvement to the preamplifier is depicted in FIG. 5. The preamplifier 500 adds an autozero section 540, to an input section 510, an output section 520, and a feedback section 530, and a power supply 502. The preamplifier works in the manner described above in FIGS. 3 and 4. Power supply 502 with positive voltage supply 504 and negative voltage supply or return 506 connects to the output sections and feedback sections of the preamplifier 500. The input section includes first and second input transistors 512 and cascode transistors 514 connected to the first and second input transistors 512. The cascode transistors 514 connect to output terminals 524 of the amplifier. The output section includes current source transistors 522 connected to the positive voltage supply 504 and to output terminals 524. The output section also includes feedback loop 530, including feedback transistors 532, 534, connected with a common source to second tail current source transistor 536. The current source circuit is completed by first tail current source transistor 518 connected between the sources of the first and second input transistors 512 and the voltage supply return 506. The second tail current source transistor 536 also connects to the voltage supply return 506 and has its gate connected to its drain. Bias voltages 523 and 526 may be applied to transistors 522 and 514, respectively, to control their operation.

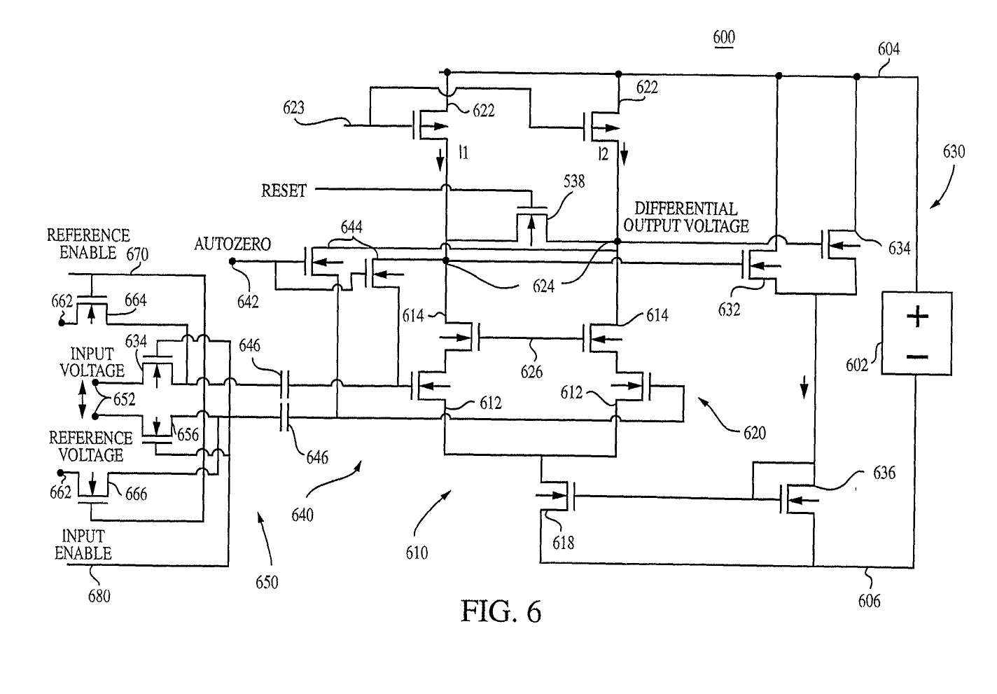

The autozero section 540 includes first and second autozero capacitors 546 connected between gates of the input transistors 512 and input terminals 552. A signal applied to combined gates 542 of the autozero transistors 544 shorts gates of the input transistors 512 to the output terminals 524. An additional explanation of the functions of the autozero capacitors is given below in the discussion of FIG. 6. The autozero section is useful because it is desirable to cancel the offset voltage of the preamplifier. Offset voltages are related to mismatches generated between “matching” transistors during manufacturing. The mismatch is a measure of the inherent variability of the manufacturing steps used in CMOS processes. One performance aspect of the preamplifier is to minimize residual offset voltages. Residual offset of the preamplifier is proportional to the inverse of available gain. The higher the gain, the less offset voltage that may remain on the preamplifier after completing an auto-zero cycle. The preamplifier embodiments of the invention remove residual offset through the autozero operation. The quicker the amplifier is able to amplify an input signal, the more time that is left for autozero operations. Therefore, the autozero signal may be applied as often as desired between input voltage sampling cycles. FIG. 5 depicts autozero transistors 544 as NMOS, but the transistors may as well be PMOS, or may even be both NMOS and PMOS.

A further improvement to the preamplifier is depicted in FIG. 6. A preamplifier 600 adds a multiplexer and comparator section 650, to an input section 610, an output section 620, a feedback section 630, autozero section 650, and a power supply 602. The preamplifier 600 works in the manner described above in conjunction with FIGS. 3, 4 and 5. Power supply 602 with positive voltage supply 604 and negative voltage supply or return 606 connects to the output sections and feedback sections of the preamplifier 600. The input section 610 includes first and second input transistors 612 and cascode transistors 614 connected to the first and second input transistors 612. The cascode transistors 614 connect to output terminals 624 of the amplifier. A bias voltage 626 may be applied to the gates of transistors 614 to control their operation.

The output section includes current source transistors 622 connected to the positive voltage supply 604 and to output terminals 624. A bias voltage 623 may be applied to the gates of transistors 622 to control their operation. The output section also includes feedback loop 630, including feedback transistors 632, 634, connected with a common source to second tail current source transistor 636.

The current source circuit is completed by first tail current source transistor 618 connected between the sources of the first and second input transistors 612 and the voltage supply return 606. The second tail current source transistor 636 also connects to the voltage supply return 606 and has its gate connected to its drain. The autozero section 640 includes first and second autozero capacitors 646 connected between gates of the input transistors 612 and the comparator section 650. A signal applied to combined gates 642 of the autozero transistors 644 shorts gates of the input transistors 612 to the output terminals 624.

The comparator section 650 includes portions for connecting a reference voltage signal and an input voltage signal, a reference enable signal, and an input enable signal. Comparator section 650 includes input voltage terminals 652 and input voltage transistors 654 and 656, connected with the autozero capacitors 646. In one embodiment, input terminals 652 are the input terminals for a time-varying input signal for the preamplifier. A differential voltage signal applied to the input terminals 652 will pass through transistors 654, 656 to capacitors 646. The input voltage will then travel through the capacitors 646 and appear at the input transistors 612 for amplification by the preamplifier 600. In one embodiment, an input enable circuit 680 connects to the gates of the input voltage transistors 654, 656, allowing for a signal to turn on the transistors and pass an input differential voltage signal.

Reference voltage terminals 662 and reference voltage transistors 664, 666, connect in parallel with the input voltage transistors 654, 656, to the autozero capacitors 646, and thus to the input transistors 612. In one embodiment, the preamplifier 600 also includes a reference enable circuit 670 connected to gates of the reference voltage transistors 664, 666. A signal applied to the gates of the reference voltage transistors 664, 666 turns on the transistors 664, 666 and allows a reference voltage signal to be applied to the autozero capacitors 646 and thence to the input transistors 612 of the preamplifier. Reference voltage transistors 664, 666, are depicted in FIG. 6 as NMOS. In other embodiments, PMOS transistors may be used. In yet other embodiments, both NMOS and PMOS transistors may be used.

The reference voltage section and reference enable sections allow a comparison of the input voltage to the reference voltage. If the input voltage is greater than the reference voltage, the signal output signal is positive. If the input voltage is less than the reference voltage, the output signal is negative.

The comparator section 650 works as follows. A control signal is applied to the gates 642 of autozero transistors 644. This shorts the output voltage of the preamplifier terminals to one plate of capacitors 644. During the auto-zero operation, no reset signal is applied, so the outputs of the preamplifier have nearly the same value as the input offset voltage. The autozero control is kept turned on and a control signal is applied to the reference enable terminal 670 and thence to the gates of transistors 664, 666. A reference voltage is then applied to terminals 662 of reference enable transistors 664 and 666 and passes through to one plate each of capacitors 646. Now, both plates of the auto-zero capacitors are connected to low-impedance voltage nodes and thus they can store charge. The stored charge corresponds to the reference voltage and output offset of the amplifier.

The output offset of the amplifier differs by a residual offset value from the input offset of the preamplifier. Following this, the reference enable transistors 664, 666 and the auto-zero transistors 644 are turned off and the reference voltage and output offset of the preamplifier are stored on the capacitors 646. A control voltage is than applied to the input enable circuit 680 and thence to the gates of differential input voltage transistors 654 and 656. An input voltage is applied to terminals 652 of transistors 654 and 656 then passes through to capacitors 646, where the voltages add or subtract from the reference voltage left by the reference and auto-zero enable operation.

Since the auto-zero transistors 644 suffer from leakage current in the turn-off state, the charge and thus the voltage degrades after a few hundred microseconds, a period of time corresponding to a few hundred thousand sampling cycles. It is therefore necessary to repeat the auto-zero and reference enable operations every few hundred microseconds. The preamplifier continually resets, auto-zeroes, and places a reference voltage on the auto-zero capacitors. When not engaged in an auto-zero operation, the preamplifier rests in the first half of every clock cycle and amplifies the difference between the input voltage and the reference voltage, comparing them in the second half of every clock cycle.

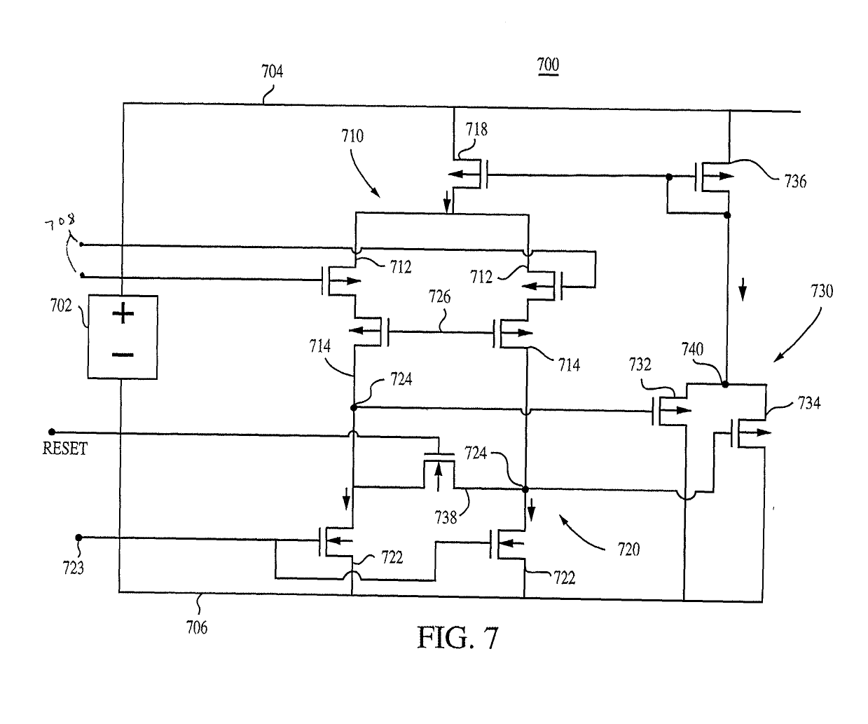

There are many ways to practice the invention. For instance, instead of depending primarily on NMOS transistors, a user may prefer PMOS transistors. FIG. 7 depicts another embodiment of the invention preamplifier 700. FIG. 7 is the PMOS version of the preamplifier circuit of FIG. 4, which featured primarily NMOS transistors. In FIG. 7, as discussed for FIG. 4, the input section 710 of preamplifier 700 includes a power supply 702 having a positive rail 704 and a negative or return rail 706. The input section 710 includes input terminals 708 connected with first and second input transistors 712, and also with first and second cascode transistors 714. The transistors are cascode connected in that the drains of the input transistors 712 are connected with the sources of cascode transistors 714. The sources of the cascode transistors connect with output terminals 724 at the drains of the cascode transistors 714. The output section 720 includes current source transistors 722 connected to the negative voltage supply or return 704, the drains of the current source transistors 722 also being connected to the output terminals 724.

First and second tail current source transistors 718 and 736 complete the current path by connecting the sources of the input transistors 712 to the voltage supply 704. A reset transistor 738 may also be connected across the output s 724 to short the terminals when desired. Bias voltages 726 and 723 control the operation of transistors 714 and 722, respectively. The preamplifier 700 adds a common mode feedback current loop 730 in order that the sum of currents I1 and I2 in the output section 720 may stay balanced with the tail current of transistors 718 and 736. The feedback loop 730 includes first and second feedback loop transistors 732, 734, joined at node 740 and connected in parallel between the second tail current transistor 736 and the voltage return 706. First and second tail source transistors 718, 736 are connected as a current mirror, having a common source at the positive voltage supply 704 and having joined gates connected to the drain of transistor 736. The direction of current in the feedback loop is as shown by the small arrow.

The feedback loop transistors 732, 734 are controlled by the output voltage, tied to the gates of common mode feedback transistors 732, 734. The operation of the circuit is as discussed for the embodiment of FIG. 4. If the current in current source transistors 722 rises, the output voltage, and the drains of transistors 722 will decrease. The voltage at the gates of common mode feedback transistors 732, 734 will also decrease, and since transistors 732, 734 are PMOS, the voltage at node 740 will also decrease. Node 740 voltage is tied to the gates of tail current transistors 718 and 736, which will see a decreased voltage. PMOS tail current transistors 718, 736 will thus turn further “on,” and the increase in current source current is matched by an increase in tail current. The feedback loop works in the opposite way for a decrease in current.

Although only a few embodiments of the invention have been discussed, other embodiments are contemplated. For instance, the reference section places a reference voltage on the autozero capacitors, and then subtracts an input voltage from the reference voltage for amplification. In another method of practicing the invention, an input voltage may be added to a known voltage and placed on the capacitors, and the reference voltage may be inverted and then subtracted from the voltage placed on the capacitors. There are many ways to practice this invention. For instance, while the preamplifier is most useful at clock speeds exceeding 1 GHz, it may be used at far slower speeds.

Preamplifiers may be required or useful in many other kinds of circuits. It is therefore intended that the foregoing description illustrates rather than limits this invention, and that it is the following claims, including all equivalents, which define this invention. Of course, it should be understood that a wide range of changes and modifications may be made to the embodiments described above. Accordingly, it is the intention of the applicants to protect all variations and modifications within the valid scope of the present invention.

What is claimed is:

1. A preamplifier, comprising:
an input section, including a first input transistor and a second input transistor connected to a first tail current source transistor, and a third and a fourth transistor connected in cascode with the first and second transistor, where the input section amplifies an input signal; and
an output section for increasing the output resistance of the preamplifier, including first and second current source transistors connected to the input section at an output of the preamplifier, where the first and second current source transistors act as load elements for the preamplifier,
wherein the preamplifier has high output resistance and produces an output signal of high gain.

2. The preamplifier of claim 1, further comprising a reset transistor connected to the output of the preamplifier, the reset transistor responsive to a control signal at a gate of the reset transistor.

3. The preamplifier of claim 1, wherein the first and second transistors of the output section are PMOS transistors.

4. The preamplifier of claim 1, further comprising a common mode feedback loop, the loop comprising two common mode feedback loop transistors connected in parallel with the current sources for the output section, the output signal applied to gates of the feedback loop transistors, and a second tail current source transistor completing the feedback loop, said second tail current source transistor connected with the first tail current source transistor as a current mirror, and a gate of the second tail source transistor connected to a drain of the second tail source transistor, wherein a common mode voltage feedback to a gate of the first tail source transistor is set by a sum of gate-to-source voltages of the feedback transistors and the second tail source transistor.

5. The preamplifier of claim 4, wherein the common mode feedback loop transistors are NMOS.

6. The preamplifier of claim 4, further comprising an autozero section, wherein the autozero section has first and second capacitors connected with the first and second input transistors, and first and second autozero transistors connected between the first and second capacitors and the outputs of the preamplifier, the autozero transistors responsive to a signal input to gates of the autozero transistors.

7. The preamplifier of claim 6, wherein first and second autozero transistors comprise NMOS transistors.

8. The preamplifier of claim 6, wherein first and second autozero transistors comprise PMOS transistors.

9. The preamplifiers of claim 6, wherein first and second autozero capacitors comprise NMOS and PMOS transistors in parallel.

10. The preamplifier of claim 6, wherein the input transistors comprise NMOS transistors.

11. The preamplifier of claim 6, further comprising a reference section, wherein the reference section has first and second input voltage transistors and first and second reference voltage transistors connected in parallel with the capacitors, gates of the input voltage transistors connected to an input enable circuit, and gates of the reference voltage transistors connected to a reference enable circuit.

12. The preamplifier of claim 11, wherein the reference voltage transistors comprise NMOS transistors.

13. The preamplifier of claim, wherein the reference voltage transistors comprise PMOS transistors.

14. The preamplifier of claim 11, wherein the reference voltage transistors comprise NMOS and PMOS transistors in parallel.

15. A preamplifier, comprising:
a first current source transistor and a second current source transistor connected to a positive voltage supply;
a first tail current source transistor, connected to a negative voltage supply;
first and second input transistors connected to the current source transistor;
first and second cascode transistors connected in series with the first and second input transistors and forming points of connection with the first and second current source transistors, said points of connection being outputs of the preamplifier,
wherein a differential voltage applied to gates of the first and second input transistors is amplified and an output signal is formed and applied to the outputs.

16. The preamplifier of claim 15, further comprising a reset transistor connected across the outputs, the reset transistor responsive to a control signal applied to a gate of the reset transistor.

17. The preamplifier of claim 15, wherein the first and second current source transistors comprise PMOS transistors.

18. The preamplifier of claim 15, further comprising a common mode feedback loop, having first and second common mode feedback transistors connected in parallel with the first and second current source transistors to the voltage supply, the gates of said first and second feedback transistors connected to the outputs, and a second tail source transistor completing the feedback loop, said second tail source transistor connected between joined said common mode feedback transistors and a negative voltage supply or return,
wherein the first and second tail source transistors are configured as a current mirror, the common source being the negative voltage supply, wherein the feedback loop acts to equalize the currents in the first and second current source transistors with the first tail current transistor.

19. The preamplifier of claim 18, wherein the common mode feedback transistors comprise NMOS transistors.

20. The preamplifier of claim 18, further comprising an autozero section, wherein the autozero section has first and second autozero capacitors connected to gates of the first and second input transistors, and first and second autozero transistors connected between the first and second autozero capacitors and the outputs of the preamplifier, the autozero transistors responsive to a signal input to gates of the autozero transistors.

21. The preamplifier of claim 20, wherein the autozero capacitors comprise NMOS transistors.

22. The preamplifier of claim 20, wherein the input voltage transistors comprise NMOS transistors.

23. The preamplifier of claim 20, further comprising a reference section having a differential section and a reference enable and input enable,
the differential section having first and second differential input transistors and first and second differential reference transistors, said differential input transistors connected to the first and second input transistors through the autozero capacitors, and said differential reference transistors connected in parallel with the first and second differential input transistors, and
a reference enable connected to gates of the reference transistors and an input enable connected to gates of the differential input transistors,
wherein a reference voltage is applied to the capacitors when a signal is applied to the gates of the reference transistors, and an input voltage is subtracted from the voltage applied to the capacitors when a signal is applied to the gates of the input enable transistors.

24. The preamplifier of claim 23, wherein the reference voltage transistors comprise NMOS transistors.

25. The preamplifier of claim 23, wherein the reference voltage transistors comprise PMOS transistors.

26. The preamplifier of claim 23, wherein the reference voltage transistors comprise NMOS transistors in parallel with PMOS transistors.

27. A preamplifier, comprising:
an input section, including a first input transistor and a second input transistor connected to a first tail current source transistor, and a third and a fourth transistor connected in cascode with the first and second transistor, where the input section amplifies an input signal; and
an output section for increasing the output resistance of the preamplifier, including first and second current source transistors connected to the input section at an output of the preamplifier, where the first and second current source transistors act as load elements for the preamplifier,
wherein the preamplifier has high output resistance and produces an output signal of high gain.

28. The preamplifier of claim 27, further comprising a reset transistor connected to the output of the preamplifier, the reset transistor responsive to a control signal at a gate of the reset transistor.

29. The preamplifier of claim 27, wherein the first and second transistors of the output section are NMOS transistors.

30. The preamplifier of claim 27, further comprising a common mode feedback loop, the loop comprising a second tail current transistor and two common mode feedback transistors connected in parallel with the current sources for the output section, the output signal applied to gates of the common mode feedback loop transistors, said second tail current source transistor connected with the first tail current source transistor as a current mirror, and a gate of the second tail source transistor connected to a drain of the second tail source transistor, wherein a common mode voltage feedback to a gate of the first tail source transistor is set by a sum of gate-to-source voltages of the feedback transistors and the second tail source transistor.

31. The preamplifier of claim 27, wherein the common mode feedback transistors are PMOS.

32. A preamplifier, comprising:
a first tail current source transistor, connected to a positive voltage supply;
a first current source transistor and a second current source transistor connected to a negative voltage supply or return;
first and second input transistors connected to the first tail current source transistor;
first and second cascode transistors connected in series with the first and second input transistors and forming points of connection with the first and second current source transistors, said points of connection being outputs of the preamplifier,
wherein a differential voltage applied to gates of the first and second input transistors is amplified and an output signal is formed and applied to the outputs.

33. The preamplifier of claim 32, further comprising a reset transistor connected across the outputs, the reset transistor responsive to a control signal applied to a gate of the reset transistor.

34. The preamplifier of claim 32, wherein the first and second current source transistors comprise NMOS transistors.

35. The preamplifier of claim 32, further comprising a common mode feedback loop, having a second tail current source transistor and first and second common mode feedback transistors connected in parallel with the first and second current source transistors to the voltage supply, the gates of said first and second feedback transistors connected to the outputs, said second tail source transistor connected between joined said feedback transistors and a positive voltage supply or return,
wherein the first and second tail source transistors are configured as a current mirror, the common source being the positive voltage supply, wherein the feedback loop acts to equalize the currents in the first tail current transistor with the currents in the first and second current source transistors.

36. The preamplifier of claim 32, wherein the common mode feedback transistors comprise PMOS transistors.
